(19) United States
(12) Patent Application Publication
(10) Pub. No.: US 2025/0164590 A1
(43) Pub. Date: May 22, 2025

(54) MAGNETIC RESONANCE IMAGING APPARATUS

(71) Applicant: CANON MEDICAL SYSTEMS CORPORATION, Otawara-shi (JP)

(72) Inventor: Kazuya OKAMOTO, Saitama Saitama (JP)

(73) Assignee: CANON MEDICAL SYSTEMS CORPORATION, Otawara-shi (JP)

(21) Appl. No.: 18/949,108

(22) Filed: Nov. 15, 2024

(30) Foreign Application Priority Data
Nov. 22, 2023 (JP) 2023-198288

(51) Int. Cl. G01R 33/36; G01R 33/34

(52) U.S. Cl. CPC G01R 33/3692; G01R 33/34

(57) ABSTRACT

A magnetic resonance imaging apparatus includes a top plate on which a reception coil for receiving a magnetic resonance signal is disposed, a top plate communication unit, and a frame communication unit. The top plate communication unit is disposed in an interior of the top plate and configured to be movable inside the top plate. The frame communication unit is disposed in a position at one end of a frame having a bore where the top plate is inserted. The magnetic resonance imaging apparatus executes communication between the top plate communication unit and the frame communication unit.

### CROSS-REFERENCE TO RELATED APPLICATIONS

This application is based upon and claims the benefit of priority from Japanese Patent Application No. 2023-198288, filed Nov. 22, 2023, the entire contents of which are incorporated herein by reference.

### FIELD

Embodiments described herein relate generally to a magnetic resonance imaging apparatus.

### BACKGROUND

Conventional magnetic resonance imaging (MRI) apparatuses apply a gradient magnetic field and a high-frequency magnetic field having a magnetic resonance frequency to a subject in a static magnetic field, detect a magnetic resonance signal from a desired cross-section, and execute imaging by image reconstruction based on the detected magnetic resonance signal.

In the above-described MRI apparatuses, a reception radio frequency (RF) coil adjusted to a desired frequency determined in accordance with the intensity of the magnetic field is used as a unit for detecting the magnetic resonance signal. A magnetic resonance signal detected by the reception RF coil is input to a connector disposed on a top plate of a table on which a subject is placed, transmitted toward a frame via a cable installed between the table and the frame, and then forwarded from the frame to a system that executes image reconstruction.

In recent years, an MRI apparatus capable of acquiring an image with higher image quality has been realized. This MRI apparatus acquires an image by imaging using magnetic resonance signals simultaneously detected by a reception RF coil that includes a plurality of reception element RF coils and is placed with respect to a subject. The reception RF coil for the above-described MRI apparatus is connected to the system via a composite cable including a plurality of coaxial cables for transmission of a plurality of detected magnetic resonance signals. Further, for the use case in which a plurality of reception RF coils is placed with respect to a subject and operated simultaneously, a plurality of connectors for connecting the plurality of reception RF coils is disposed on the top plate of the table. Consequently, a large number of composite cables are installed between the table and the frame, which causes complexity in the MRI apparatus, difficulty in installation of the MRI apparatus, and an increase in cost.

An MRI apparatus including dockable table in which a top plate and a table are configured to be separable and movable from a frame has also been emerged as an MRI apparatus with improved user convenience. This MRI apparatus includes a large connector for a connection with a plurality of cables between the table and the frame. This configuration is disadvantageous because of an increase in a weight of the movable table and an additional mechanisms for the connection between the table and the frame.

In view of the above-described issue, there is a demand to reduce the number of cables between the table and the frame of the MRI apparatus.

For the purpose of reducing the cables, wireless transmission of received signals, control signals, and electric power is expected, and various techniques have been proposed so far. In theory, it is desirable that data and electric power are wirelessly transmitted and received to/from the system through a reception RF coil to which a wireless data transmission/reception function and an electric power reception function are provided. However, at present, a unit realizing the above-described functions with sufficient performance have yet to be achieved.

### BRIEF DESCRIPTION OF THE DRAWINGS

FIG. 1 is a diagram illustrating a configuration example of a magnetic resonance imaging (MRI) apparatus according to a first exemplary embodiment;

FIG. 2A is a diagram illustrating an example of configuration of a top plate and a table included in the MRI apparatus according to the first exemplary embodiment;

FIG. 2B is a diagram illustrating an example of configuration of the top plate and the table included in the MRI apparatus according to the first exemplary embodiment;

FIG. 2C is a diagram illustrating an example of configuration of the top plate and the table included in the MRI apparatus according to the first exemplary embodiment;

FIG. 3 is a diagram illustrating an example of configuration of a data transmission/reception, power reception unit, a data transmission/reception, and power transmission unit included in the MRI apparatus according to the first exemplary embodiment,

FIG. 4A is a diagram illustrating an example of configuration of a top plate and a table included in an MRI apparatus according to a second exemplary embodiment;

FIG. 4B is a diagram illustrating an example of configuration of the top plate and the table included in the MRI apparatus according to the second exemplary embodiment; and

FIG. 4C is a diagram illustrating an example of configuration of the top plate and the table included in the MRI apparatus according to the second exemplary embodiment.

### DETAILED DESCRIPTION

A magnetic resonance imaging (MRI) apparatus according to an exemplary embodiment includes a top plate on which a reception coil for receiving a magnetic resonance signal is disposed, a top plate communication unit, and a frame communication unit. The top plate communication unit, which is disposed in the interior of the top plate, is configured to be movable inside the top plate. The frame communication unit is disposed in a position at one end of a frame having a bore where the top plate is inserted. The MRI apparatus executes communication between the top plate communication unit and the frame communication unit.

Various Embodiments will be described hereinafter with reference to the accompanying drawings.

### First Exemplary Embodiment

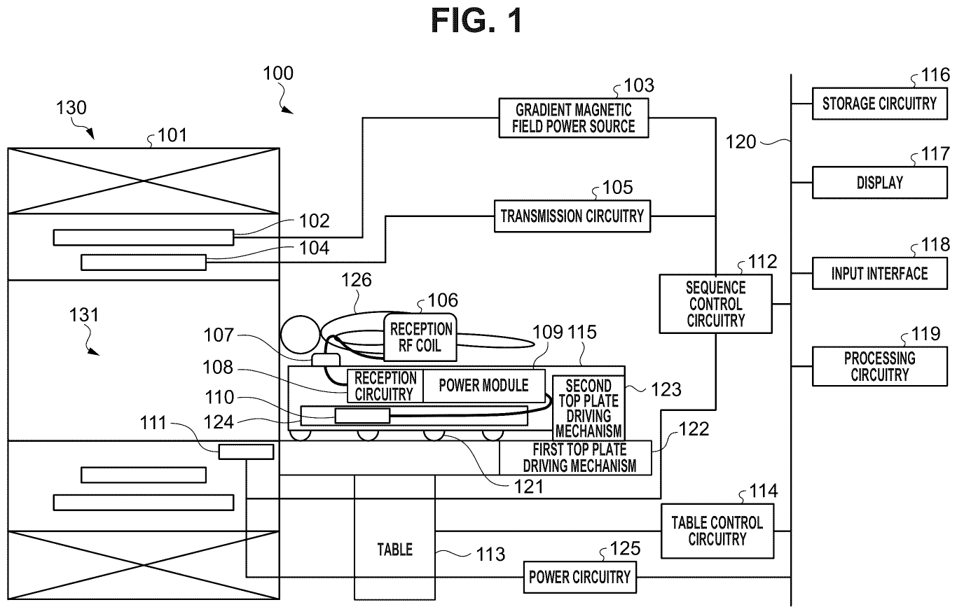

FIG. 1 is a diagram illustrating a configuration example of an MRI apparatus 100 according to a first exemplary embodiment.

As illustrated in FIG. 1, the MRI apparatus 100 according to the present exemplary embodiment includes a static magnetic field magnet 101, a gradient magnetic field coil 102, a gradient magnetic field power source 103, a reception radio frequency (RF) coil 106, a top plate 115, a table 113 on which the top plate 115 is placed, a table control circuitry 114, a transmission RF coil 104, a transmission circuitry 105, a frame 130 which houses the static magnetic field magnet 101, the gradient magnetic field coil 102, and the transmission RF coil 104, a power circuitry 125, a sequence control circuitry 112, a bus 120, an input interface 118, a display 117, a storage circuitry 116, and a processing circuitry 119. The MRI apparatus 100 may include a hollow cylindrical-shaped shim coil in a position between the static magnetic field magnet 101 and the gradient magnetic field coil 102.

The static magnetic field magnet 101 is a magnet having a hollow cylindrical shape and generates a uniform static magnetic field (B0) in its internal space. Examples of a magnet that is used as the static magnetic field magnet 101 include a superconducting magnet. A shim coil (not illustrated) having a hollow cylindrical shape may be disposed on the inner side of the static magnetic field magnet 101. The shim coil is connected to a shim coil power source (not illustrated) and equalizes the static magnetic field generated by the static magnetic field magnet 101 with electric power supplied from the shim coil power source.

The gradient magnetic field coil 102 is a coil having a hollow cylindrical shape and disposed on the inner side of the static magnetic field magnet 101. The gradient magnetic field coil 102 is a combination of three coils respectively corresponding to X, Y, and Z axes orthogonal to each other. The Z-axis direction is same as a direction of the static magnetic field. The Y-axis direction is a vertical direction, and the X-axis direction is perpendicular to the Z-axis and the Y-axis. The three coils included in the gradient magnetic field coil 102 individually receive electric currents supplied from the gradient magnetic field power source 103, and generate gradient magnetic fields whose magnetic field intensities are respectively changed along the X, Y, and Z axes.

For example, the gradient magnetic fields in the X-axis, Y-axis, and Z-axis, generated by the gradient magnetic field coil 102, correspond to a frequency encoding gradient magnetic field (also called a readout gradient magnetic field), a phase encoding gradient magnetic field, and a slice-selective gradient magnetic field, respectively. The frequency encoding gradient magnetic field is used to change a frequency of a magnetic resonance (MR) signal in accordance with a spatial location. The phase encoding gradient magnetic field is used to change a phase of the MR signal in accordance with the spatial location. The slice-selective gradient magnetic field is used to optionally determine an imaging cross-section.

The gradient magnetic field power source 103 is a power source apparatus which supplies electric currents to the gradient magnetic field coil 102 under the control of the sequence control circuitry 112.

The table 113 is a device having the top plate 115 on which a subject 126 is placed. Under the control of the table control circuitry 114, the table 113 inserts the top plate 115, on which the subject 126 is placed, into a bore 131 in the frame 130. Normally, the table 113 is installed in an examination room where the MRI apparatus 100 is installed, in a state where a lengthwise direction of the table 113 is parallel to a central axis of the static magnetic field magnet 101.

Herein, insertion of the top plate 115 into the bore 131 is executed by a first top plate driving mechanism 122 disposed on the table 113 and a second top plate driving mechanism 123 disposed on the top plate 115 in cooperation with each other under the control of the table control circuitry 114. Normally, the first top plate driving mechanism 122 and the second top plate driving mechanism 123 are coupled together with a belt to move the top plate 115 having top plate wheels 121.

The table control circuitry 114 controls the table 113. In accordance with an instruction input by an operator via the input interface 118, the table control circuitry 114 drives the table 113 to move the top plate 115 in a lengthwise direction and a vertical direction.

The transmission RF coil 104 is a radio frequency (RF) coil disposed on the inner side of the gradient magnetic field coil 102. The transmission RF coil 104 receives a high-frequency pulse (RF pulse) supplied from the transmission circuitry 105 and generates a transmission RF wave corresponding to a high-frequency magnetic field. Examples of the transmission RF coil 104 include a whole body (WB) coil. The WB coil may be used as a transmission/reception RF coil.

Under the control of the sequence control circuitry 112, the transmission circuitry 105 supplies a high-frequency pulse modulated by a Lamour frequency to the transmission RF coil 104. Specifically, the transmission circuitry 105 includes an oscillation unit, a phase selection unit, a frequency conversion unit, an amplitude modulation unit, and a high-frequency power amplification unit. The oscillation unit generates a high-frequency signal having a unique resonance frequency in an atomic nucleus in the static magnetic field. The phase selection unit selects a phase of the above-described high-frequency signal. The frequency conversion unit converts the frequency of the high-frequency signal output from the phase selection unit. The amplitude modulation unit modulates the amplitude of the high-frequency signal output from the frequency modulation unit according to a sinc function. The high-frequency power amplification unit amplifies the high-frequency signal output from the amplitude modulation unit. As a result of the operations executed by the respective units, the transmission circuitry 105 outputs the high-frequency pulse corresponding to the Lamor frequency to the transmission RF coil 104.

In the present exemplary embodiment, the MRI apparatus 100 transmits data received by the reception RF coil 106 to the sequence control circuitry 112, and transmits a control signal output from the sequence control circuitry 112 to a reception circuitry 108 via a data transmission/reception and power reception unit 110 disposed on the top plate 115 and a data transmission/reception and power transmission unit 111 disposed in a position on the inner side of the bore 131 in the frame 130 which is close to the table 113. The MRI apparatus 100 further transmits electric power supplied from the power circuitry 125 to a power module 109 via the data transmission/reception and power reception unit 110 disposed for the top plate 115 and the data transmission/reception and power transmission unit 111 disposed for the frame 130. The power module 109 supplies electric power to the reception RF coil 106 and the reception circuitry 108. A unit movable space 124 is provided in the interior of the top plate 115, and the data transmission/reception and power reception unit 110 is movably disposed in the unit movable space 124.

The reception RF coil 106 is placed on an imaging portion of the subject 126 placed on the top plate 115, and receives an MR signal that is radiated from the subject 126 due to the high-frequency magnetic field. More specifically, after placement of the reception RF coil 106 on the imaging portion of the subject 126, the reception RF coil 106 is moved to an imaging area within the bore 131 by the top plate 115, and receives the MR signal radiated from the subject 126. Then, the reception RF coil 106 outputs the received MR signal to the reception circuitry 108 via a reception RF coil connector 107 disposed on the top plate 115.

Under the control of the sequence control circuitry 112, the reception circuitry 108 generates magnetic resonance data (hereinafter, called MR data), which is digitized complex data, based on the MR signal output from the reception RF coil 106. More specifically, the reception circuitry 108 executes various types of signal processing, such as preamplification, intermediate frequency conversion, phase detection, low-frequency amplification, and filtering, on the MR signal output from the reception RF coil 106. Then, the reception circuitry 108 executes analog-to-digital (A/D) conversion on the data obtained by execution of the various types of signal processing. The reception circuitry 108 executes sampling on the data converted through the A/D conversion. Through the above-described processing, the reception circuitry 108 generates MR data. The reception circuitry 108 outputs the generated MR data to the data transmission/reception and power reception unit 110. The MR data generated by the reception circuitry 108 is also called raw data.

The data transmission/reception and power reception unit 110 transmits the MR data output from the reception circuitry 108 to the data transmission/reception and power transmission unit 111, and transmits the control signal output from the sequence control circuitry 112, which has received the control signal from the data transmission/reception and power transmission unit 111, to the reception circuitry 108. Herein, a clock signal to be used for the A/D conversion is also included in the control signal. Further, the data transmission/reception and power reception unit 110 supplies electric power transmitted from the data transmission/reception and power transmission unit 111 to the power module 109.

The data transmission/reception and power transmission unit 111 transmits the MR data received from the data transmission/reception and power reception unit 110 to the sequence control circuitry 112, and transmits the control signal output from the sequence control circuitry 112 to the data transmission/reception and power reception unit 110. Further, the data transmission/reception and power transmission unit 111 transmits electric power supplied from the power circuitry 125 to the data transmission/reception and power reception unit 110.

In accordance with pulse sequence information output from the processing circuitry 119, the sequence control circuitry 112 controls the gradient magnetic field power source 103, the transmission circuitry 105, and the reception circuitry 108 to execute imaging on the subject 126. The pulse sequence information defines a magnitude and a time span of the electric current to be supplied to the gradient magnetic field coil 102 from the gradient magnetic field power source 103, a timing for supplying the electric current to the gradient magnetic field coil 102 from the gradient magnetic field power source 103, a magnitude of the RF pulse to be supplied to the transmission RF coil 104 from the transmission circuitry 105, a timing for supplying the RF pulse to the transmission RF coil 104 from the transmission circuitry 105, and a timing for receiving the MR signal by the reception circuitry 108. A magnitude of the electric current to be supplied to the gradient magnetic field coil 102 from the gradient magnetic field power source 103 corresponds to a waveform of the gradient magnetic field in accordance with the pulse sequence.

The bus 120 is a transmission path through which data is transmitted and received by the input interface 118, the display 117, the storage circuitry 116, and the processing circuitry 119. Various vital signal measurement devices and external storage apparatuses may be connected to the bus 120 via a network as appropriate.

The input interface 118 accepts various instructions and information from an operator. For example, the input interface 118 is a circuitry relating to a pointing device, such as a mouse, or an input device, such as a keyboard. The input interface 118 is not limited to a circuitry relating to physical operation units, such as the mouse and the keyboard. For example, an electric signal processing circuitry which receives an electric signal corresponding to an input operation from an external input device disposed separately from the MRI apparatus 100, and outputs the received electric signal to various circuitries may also be included in the examples of the input interface 118.

Under the control of the processing circuitry 119, the display 117 displays various types of information, such as MR images, reconstructed through an image generation function. Examples of the display 117 include a display device, such as a cathode ray tube (CRT) display, a liquid crystal display, an organic electro-luminescence (EL) display, a light emitting diode (LED) display, a plasma display, or another optional display or monitor known in this technical field.

The storage circuitry 116 stores MR data arrayed in a k-space through a data array function and image data generated by an image generation function. The storage circuitry 116 stores imaging conditions including various imaging protocols and imaging parameters for prescribing the imaging protocols. The storage circuitry 116 stores programs corresponding to various functions that are executed by the processing circuitry 119. Examples of the storage circuitry 116 include a random access memory (RAM), a semiconductor memory device, such as a flash memory, a hard disk drive, a solid state drive, or an optical disk. The storage circuitry 116 may be a compact disk read only memory (CD-ROM) drive, a digital versatile disk (DVD) drive, or a driving device which reads and writes various types of information from/into a portable storage medium, such as a flash memory.

The processing circuitry 119 generally controls the MRI apparatus 100. For example, the processing circuitry 119 is implemented by a processor. The processing circuitry 119 has a system control function, a data array function, an image generation function, a reference value setting function, an error estimation function, a correction function, and a pulse calculation function. Various functions executed by each of the system control function, the data array function, the image generation function, the reference value setting function, the error estimation function, the correction function, and the pulse calculation function are stored in the storage circuitry 116 in the form of program executable by a computer. The processing circuitry 119 implements functions corresponding to the programs by reading a program corresponding to each of the functions from the storage circuitry 116 and executing the program.

More specifically, the processing circuitry 119 generally controls the MRI apparatus 100 through the system control function. More specifically, the processing circuitry 119 reads out a system control program stored in the storage circuitry 116, loads the system control program on a memory, and controls each of the circuitries of the MRI apparatus 100 according to the loaded system control program.

In the example illustrated in FIG. 1, various functions are implemented by a single circuitry, i.e., the processing circuitry 119. However, for example, a plurality of independent processors are combined to each other to constitute the processing circuitry 119, so that the processors may implement the functions by respectively executing the programs. In other words, the above-described functions may respectively be provided as programs, and each of the programs may be executed by one processing circuitry. Alternatively, a specific function may be implemented by a dedicated independent program execution circuitry. Further, in the example illustrated in FIG. 1, a single storage circuitry, i.e., the storage circuitry 116, stores programs respectively corresponding to the functions. However, the present exemplary embodiment is not limited thereto. For example, a plurality of storage circuitries may be disposed separately, and the processing circuitry 119 may execute a corresponding program by reading the program from the individual storage circuitry.

The table control circuitry 114, the transmission circuitry 105, the reception circuitry 108, the data transmission/reception and power reception unit 110, the data transmission/reception and power transmission unit 111, and the sequence control circuitry 112 are similarly implemented by the processing circuitries, such as processors.

Herein, the term “processors” used in the above descriptions refers to circuitries, such as a central processing unit (CPU), a graphics processing unit (GPU), an application specific integrated circuit (ASIC), a programmable logic device (e.g., a simple programmable logic device (SPLD)), a complex programmable logic device (CPLD), and a field programmable gate array (FPGA).

The processors implement various functions by reading and executing programs stored in the storage circuitry 116. Each of the programs may directly be embedded in a circuitry of a processor instead of being stored in the storage circuitry 116. In this case, the processor implements the function by reading and executing the program embedded in the circuitry.

With the above-described configuration, the MRI apparatus 100 according to the present exemplary embodiment is configured in such a manner that the number of cables installed between the table 113 and the frame 130 is reduced.

More Specifically, in the present exemplary embodiment, the data transmission/reception and power reception unit 110, disposed in the interior of the top plate 115, is configured to be movable inside the top plate 115. Further, the data transmission/reception and power transmission unit 111 is disposed in a position at one end of the frame 130 having the bore 131 where the top plate 115 is inserted. Then, the MRI apparatus 100 executes communication between the data transmission/reception and power reception unit 110 and the data transmission/reception and power transmission unit 111. The data transmission/reception and power reception unit 110 is an example of a top plate communication unit. The data transmission/reception and power transmission unit 111 is an example of a frame communication unit.

In the present exemplary embodiment, the table control circuitry 114 inserts the top plate 115 into the bore 131. Then, the MRI apparatus 100 causes the data transmission/reception and power reception unit 110 to move together with the top plate 115 until the data transmission/reception and power reception unit 110 is positioned in a communication position where communication between the data transmission/reception and power reception unit 110 and the data transmission/reception and power transmission unit 111 is possible, and causes the data transmission/reception and power reception unit 110 to stop at the communication position regardless of an insertion position of the top plate 115 after the data transmission/reception and power reception unit 110 is positioned in the communication position. Herein, the table control circuitry 114 is an example of a top plate insertion unit.

More specifically, in the present exemplary embodiment, the sequence control circuitry 112 controls the position of the data transmission/reception and power reception unit 110 inside the top plate 115 to cause the data transmission/reception and power reception unit 110 to move together with the top plate 115 until the data transmission/reception and power reception unit 110 is positioned in the communication position, and to cause the data transmission/reception and power reception unit 110 to stop at the communication position regardless of an insertion position of the top plate 115 after the data transmission/reception and power reception unit 110 is positioned in the communication position. Herein, the sequence control circuitry 112 is an example of a communication position control unit.

In the present exemplary embodiment, communication executed between the data transmission/reception and power reception unit 110 and the data transmission/reception and power transmission unit 111 includes transmission of MR data obtained by digitization of an MR signal received by the reception RF coil 106 and transmission of electric power to be supplied to the reception RF coil 106. The reception RF coil 106 is an example of a reception coil.

In the present exemplary embodiment, communication between the data transmission/reception and power reception unit 110 and the data transmission/reception and power transmission unit 111 is executed wirelessly.

Hereinafter, the above-described configuration of the MRI apparatus 100 according to the present exemplary embodiment is described in detail.

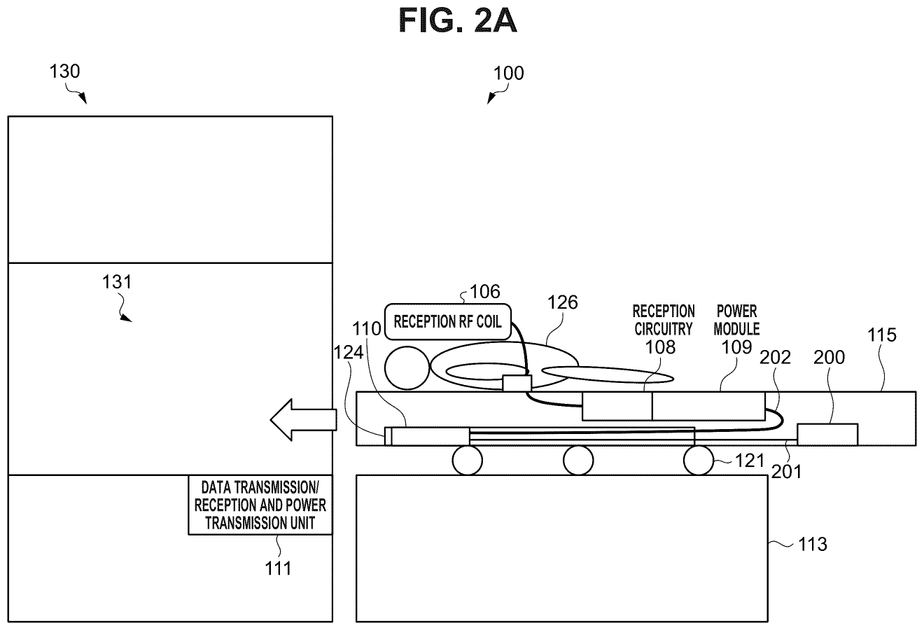

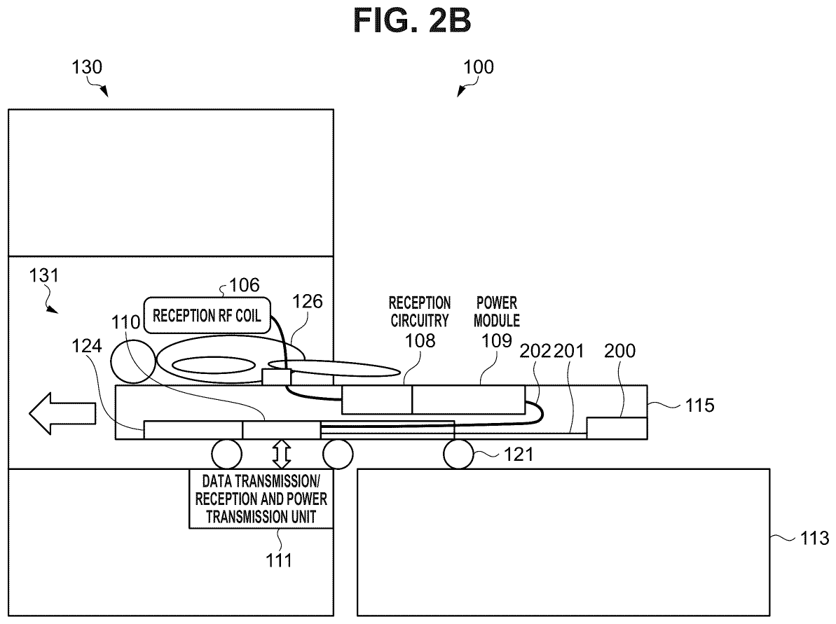

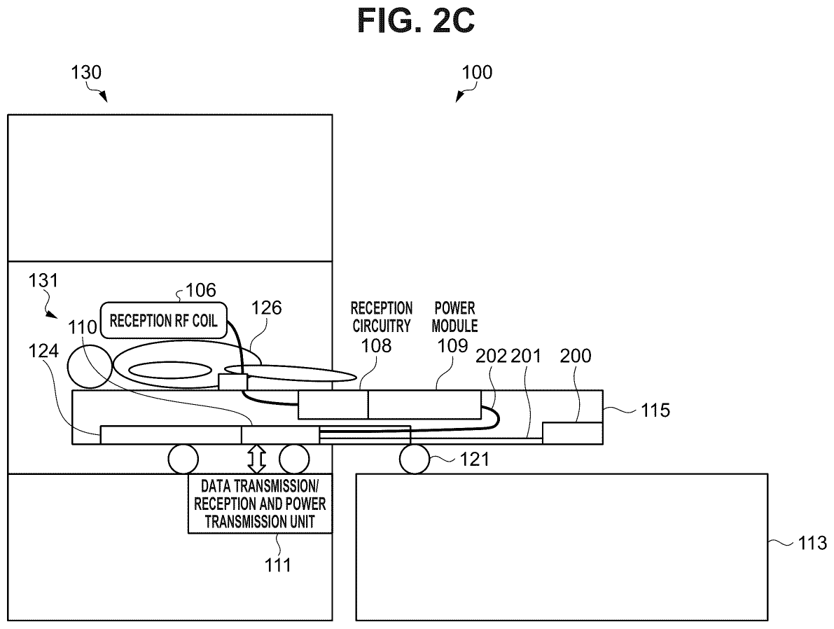

FIGS. 2A to 2C are diagrams illustrating an example of configuration of the top plate 115 and the table 113 included in the MRI apparatus 100 according to the first exemplary embodiment. Specifically, FIGS. 2A to 2C illustrate the operation executed by the data transmission/reception and power reception unit 110 in the present exemplary embodiment in a case where the top plate 115 is moved.

For example, as illustrated in FIGS. 2A to 2C, the data transmission/reception and power reception unit 110 is connected to the reception circuitry 108 and the power module 109 through an optical fiber and a power cable 202. MR data output from the reception circuitry 108 is transmitted to the data transmission/reception and power reception unit 110 via the optical fiber, and electric power supplied from the power circuitry 125 is transmitted to the power module 109 via the power cable 202.

The data transmission/reception and power reception unit 110 is coupled with a data transmission/reception and power reception unit driving circuitry 200 via a unit coupling mechanism 201, and the movement of the data transmission/reception and power reception unit 110 within the unit movable space 124 is controlled by the data transmission/reception and power reception unit driving circuitry 200. The top plate 115 includes the top plate wheels 121 and is moved into the bore 131 by the first top plate driving mechanism 122 disposed on the table 113 and the second top plate driving mechanism 123 disposed on the top plate 115.

First, as illustrated in FIG. 2A, when the top plate 115 starts moving into the bore 131, the data transmission/reception and power reception unit 110 is moved together with the top plate 115 while being housed within the unit movable space 124 until the data transmission/reception and power reception unit 110 is positioned in a vicinity of the data transmission/reception and power transmission unit 111 disposed on the frame 130.

Then, as illustrated in FIG. 2B, when the data transmission/reception and power reception unit 110 is positioned in a vicinity of the data transmission/reception and power transmission unit 111 disposed on the frame 130, the data transmission/reception and power reception unit driving circuitry 200 starts controlling of the position of the data transmission/reception and power reception unit 110 within the unit movable space 124 to cause the data transmission/reception and power reception unit 110 to stop in a vicinity of the data transmission/reception and power transmission unit 111.

Thereafter, as illustrated in FIG. 2C, when the imaging portion of the subject 126 is positioned in the imaging area of the frame 130, movement of the top plate 115 is stopped. At the same time, the data transmission/reception and power reception unit driving circuitry 200 stops controlling of the position of the data transmission/reception and power reception unit 110.

As described above, by positioning and stopping the data transmission/reception and power reception unit 110 in a vicinity of the data transmission/reception and power transmission unit 111 disposed on the frame 130, the data transmission/reception and power reception unit 110 and the data transmission/reception and power transmission unit 111 stably communicate with each other.

Herein, the above-described control of the positioning of the data transmission/reception and power reception unit 110 is executed by the sequence control circuitry 112 controlling the data transmission/reception and power reception unit driving circuitry 200. Then, transmission of MR data from the reception circuitry 108 to the sequence control circuitry 112, transmission of a control signal from the sequence control circuitry 112 to the reception circuitry 108, and transmission of electric power to be supplied to the power module 109 from the power circuitry 125 are executed via the data transmission/reception and power reception unit 110 and the data transmission/reception and power transmission unit 111.

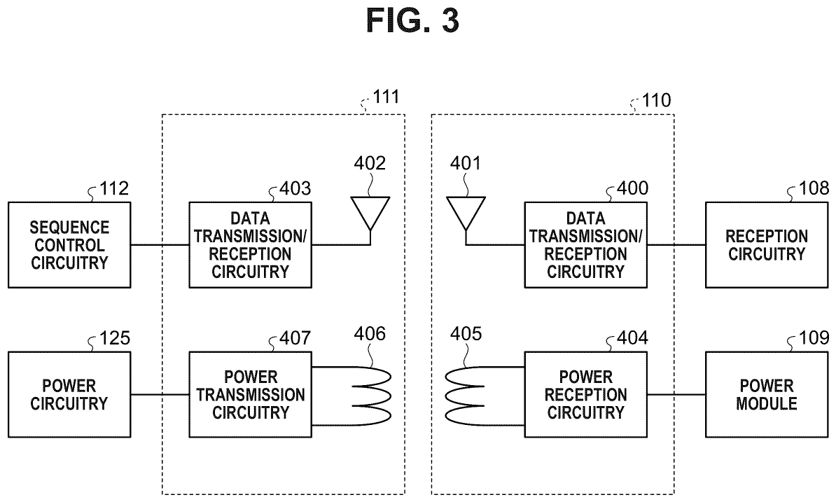

FIG. 3 is a diagram illustrating an example of configuration of the data transmission/reception and power reception unit 110 and the data transmission/reception and power transmission unit 111 included in the MRI apparatus 100 according to the first exemplary embodiment.

As illustrated in FIG. 3, for example, the data transmission/reception and power reception unit 110 includes a data transmission/reception circuitry 400 and a power reception circuitry 404.

The data transmission/reception circuitry 400 processes the MR data output from the reception circuitry 108 into data of a wirelessly-transmittable format, and transmits the processed data to the data transmission/reception and power transmission unit 111 via a transmission/reception antenna 401. Further, the data transmission/reception circuitry 400 receives a control signal output from the sequence control circuitry 112 from the data transmission/reception and power transmission unit 111 via the transmission/reception antenna 401. An original clock signal to be used for A/D conversion that is executed on the MR signal by the reception circuitry 108 is included in the control signal.

The power reception circuitry 404 detects and rectifies an electric power signal received from a power transmission coil 406 of the data transmission/reception and power transmission unit 111 via a power reception coil 405, takes out the electric power signal as direct current (DC), and transmits the DC to the power module 109. To generate a voltage of a type to be used, the power module 109 may include a DC-DC converter. Further, the power reception circuitry 404 and the power module 109 may include rechargeable batteries for storing the received electric power.

The data transmission/reception and power transmission unit 111 includes a data transmission/reception circuitry 403 and a power transmission circuitry 407.

The data transmission/reception circuitry 403 restores the signal of the processed MR data in a wirelessly-transmittable format, which has been received from the data transmission/reception and power reception unit 110 via a transmission/reception antenna 402, to MR data, and transmits the restored MR data to the sequence control circuitry 112. Further, the data transmission/reception circuitry 403 transmits a control signal output from the sequence control circuitry 112 to the data transmission/reception and power reception unit 110 via the transmission/reception antenna 402.

The power transmission circuitry 407 modulates electric power output from the power circuitry 125 into electric power of an appropriate frequency, and transmits the electric power to the power reception coil 405 of the data transmission/reception and power transmission unit 111 via the power transmission coil 406. Normally, a frequency at the time of transmitting the electric power is hundreds of hertz to tens of kilohertz.

As described above, in the first exemplary embodiment, the data transmission/reception and power reception unit 110, which is disposed in the interior of the top plate 115, is configured to be movable inside the top plate 115. Further, the data transmission/reception and power transmission unit 111 is disposed in a position at one end of the frame 130 having the bore 131 where the top plate 115 is inserted. With this configuration, the MRI apparatus 100 executes communication between the data transmission/reception and power reception unit 110 and the data transmission/reception and power transmission unit 111.

In the first exemplary embodiment, the table control circuitry 114 inserts the top plate 115 into the bore 131. Then, the MRI apparatus 100 causes the data transmission/reception and power reception unit 110 to move together with the top plate 115 until the data transmission/reception and power reception unit 110 is positioned in the communication position where communication between the data transmission/reception and power reception unit 110 and the data transmission/reception and power transmission unit 111 is possible, and causes the data transmission/reception and power reception unit 110 to stop at the communication position regardless of an insertion position of the top plate 115 after the data transmission/reception and power reception unit 110 is positioned in the communication position.

In the first exemplary embodiment, the sequence control circuitry 112 controls the position of the data transmission/reception and power reception unit 110 inside the top plate 115 to cause the data transmission/reception and power reception unit 110 to move together with the top plate 115 until the data transmission/reception and power reception unit 110 is positioned in the communication position, and to cause the data transmission/reception and power reception unit 110 to stop at the communication position regardless of an insertion position of the top plate 115 after the data transmission/reception and power reception unit 110 is positioned in the communication position.

While, in the above-described exemplary embodiment, communication executed between the data transmission/reception and power reception unit 110 and the data transmission/reception and power transmission unit 111 includes both the transmission of the MR signal, which has been received by the reception RF coil 106 and digitized to MR data, and the transmission of electric power to be supplied to the reception RF coil 106, the communication may include only one of the above-described transmission.

While, in the above-described exemplary embodiment, communication between the data transmission/reception and power reception unit 110 and the data transmission/reception and power transmission unit 111 is executed wirelessly, the communication may be executed through wired communication.

For example, the MR data may be transmitted through the wireless communication between the data transmission/reception and power reception unit 110 and the data transmission/reception and power transmission unit 111, and the electric power may be transmitted through the wired communication via the cable installed between the table 113 and the frame 130.

Alternatively, the electric power may be transmitted through the wireless communication between the data transmission/reception and power reception unit 110 and the data transmission/reception and power transmission unit 111, and the MR data may be transmitted through the wired communication via the cable installed between the table 113 and the frame 130. In this case, for example, the MR data may be transmitted via an optical fiber.

According to the above-described configuration, the data transmission/reception and power reception unit 110 movable inside the top plate 115 and the data transmission/reception and power transmission unit 111 disposed on the frame 130 communicate with each other, which removes or reduces the cables between the table 113 and the frame 130.

Therefore, according to the first exemplary embodiment, the number of cables installed between the table 113 and the frame 130 is reduced.

Consequently, the issues such as complexity in the MRI apparatus, difficulty in installation of the MRI apparatus, and an increase in cost are solvable. Further, application of the present exemplary embodiment to the MRI apparatus including a dockable table leads to a solution to an increase in weight of the table and for preventing addition of mechanisms for supporting the connection between the table and the frame.

The above-described MRI apparatus 100 according to the first exemplary embodiment is also implementable by appropriately modifying the configuration of the data transmission/reception and power reception unit 110 and the data transmission/reception and power transmission unit 111. A variation example relating to the first exemplary embodiment is described below as another exemplary embodiment. In the below-described exemplary embodiment, redundant descriptions of contents overlapping with the contents described in the first exemplary embodiment are omitted, and points different from the first exemplary embodiment are mainly described.

### Second Exemplary Embodiment

For example, in the above-described first exemplary embodiment, the sequence control circuitry 112 controls the position of the data transmission/reception and power reception unit 110 by controlling the data transmission/reception and power reception unit driving circuitry 200. However, the exemplary embodiment is not limited thereto. For example, the position of the data transmission/reception and power reception unit 110 may be controlled by a coupling mechanism for coupling the data transmission/reception and power reception unit 110 and the data transmission/reception and power transmission unit 111. Hereinafter, an example of the above-described case is described as a second exemplary embodiment.

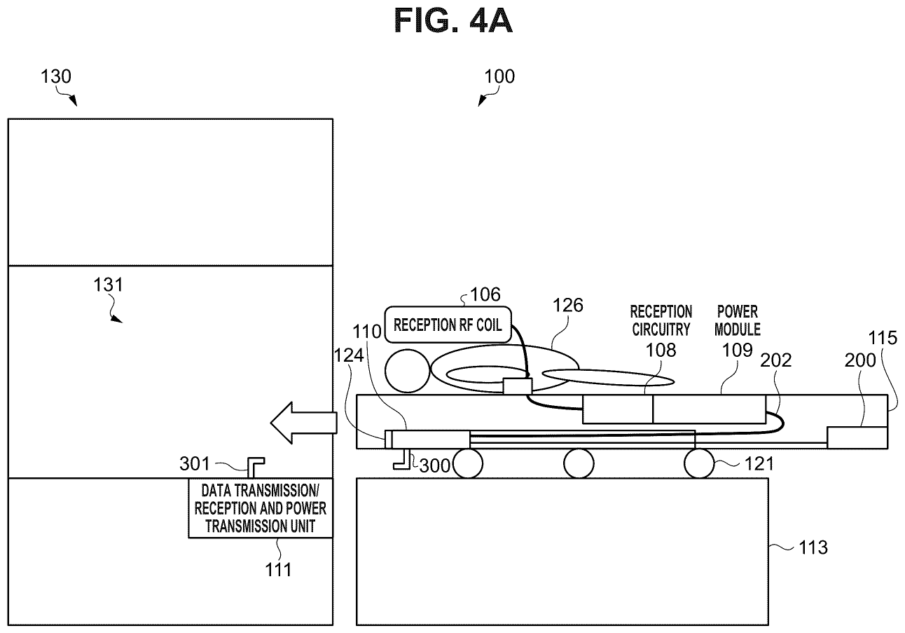

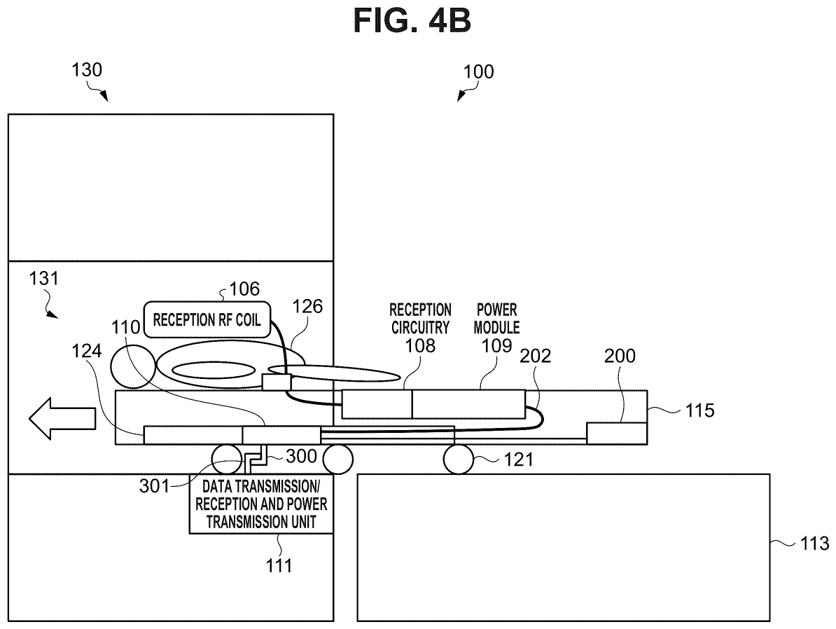

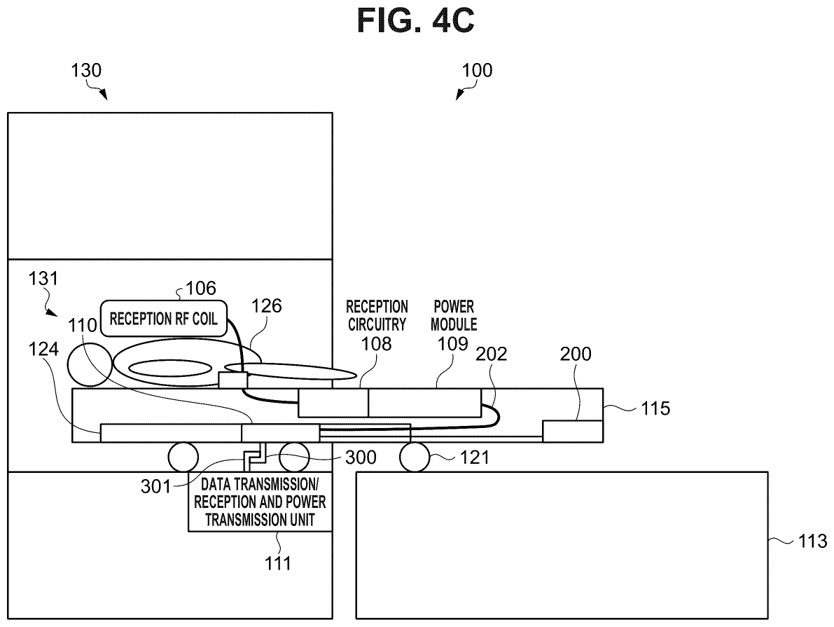

FIGS. 4A to 4C are diagrams illustrating an example of configuration of the top plate 115 and the table 113 included in the MRI apparatus 100 according to the second exemplary embodiment. More specifically, FIGS. 4A to 4C illustrate the operation in the present exemplary embodiment that is executed by the data transmission/reception and power reception unit 110 in a movement of the top plate 115.

For example, as illustrated in FIGS. 4A to 4C, in the present exemplary embodiment, a first transmission/reception unit coupling mechanism 300 is disposed on the data transmission/reception and power reception unit 110 included in the table 113, and a second transmission/reception unit coupling mechanism 301 is disposed on the data transmission/reception and power transmission unit 111 included in the frame 130. In a case where the data transmission/reception and power reception unit 110 is moved to a communication position where communication between the data transmission/reception and power reception unit 110 and the data transmission/reception and power transmission unit 111 is possible, the first transmission/reception unit coupling mechanism 300 and the second transmission/reception unit coupling mechanism 301 are coupled with each other, which causes the data transmission/reception and power reception unit 110 to stop at the communication position regardless of the insertion position of the top plate 115. Herein, the first transmission/reception unit coupling mechanism 300 is an example of a first coupling mechanism. Further, the second transmission/reception unit coupling mechanism 301 is an example of a second coupling mechanism.

As illustrated in FIG. 4A, when the top plate 115 starts moving into the bore 131, the data transmission/reception and power reception unit 110 is moved together with the top plate 115 while being housed within the unit movable space 124 until the data transmission/reception and power reception unit 110 is positioned in a vicinity of the data transmission/reception and power transmission unit 111 disposed on the frame 130

Then, as illustrated in FIG. 4B, in a case where the data transmission/reception and power reception unit 110 is positioned in a vicinity of the data transmission/reception and power transmission unit 111 disposed on the frame 130, the first transmission/reception unit coupling mechanism 300 and the second transmission/reception unit coupling mechanism 301 are coupled with each other, which causes the movement of the data transmission/reception and power reception unit 110 to be stopped.

As illustrated in FIG. 4C, at a timing when the imaging portion of the subject 126 is positioned in the imaging area of the frame 130, movement of the top plate 115 is stopped. The data transmission/reception and power reception unit 110 and the data transmission/reception and power transmission unit 111 are kept stopped at a position where the first transmission/reception unit coupling mechanism 300 and the second transmission/reception unit coupling mechanism 301 are coupled with each other as illustrated in FIG. 4B.

As described above, by positioning and stopping the data transmission/reception and power reception unit 110 in a vicinity of the data transmission/reception and power transmission unit 111 disposed on the frame 130, stable communication between the data transmission/reception and power reception unit 110 and the data transmission/reception and power transmission unit 111 is realized.

As described above, in the second exemplary embodiment, the first transmission/reception unit coupling mechanism 300 disposed on the data transmission/reception and power reception unit 110 included in the table 113 and the second transmission/reception unit coupling mechanism 301 disposed on the data transmission/reception and power transmission unit 111 included in the frame 130 are coupled with each other in a case where the data transmission/reception and power reception unit 110 is moved to the communication position where communication between the data transmission/reception and power reception unit 110 and the data transmission/reception and power transmission unit 111 is possible, which causes the data transmission/reception and power reception unit 110 to stop at the communication position regardless of the insertion position of the top plate 115.

According to the above-described configuration, a coupling between the first transmission/reception unit coupling mechanism 300 and the second transmission/reception unit coupling mechanism 301 is realized simply by a mechanical coupling, which results in that placement of the data transmission/reception and power transmission unit 111 is easily controlled in comparison with the configuration described in the first exemplary embodiment.

While, in the first exemplary embodiment, communication between the data transmission/reception and power reception unit 110 and the data transmission/reception and power transmission unit 111 is executed wirelessly, according to the second exemplary embodiment, the communication may be executed through wired communication via the first transmission/reception unit coupling mechanism 300 and the second transmission/reception unit coupling mechanism 301.

For example, a connector may be disposed on each coupling portion of the first transmission/reception unit coupling mechanism 300 and the second transmission/reception unit coupling mechanism 301, and communication between the data transmission/reception and power reception unit 110 and the data transmission/reception and power transmission unit 111 may be executed via the connectors.

In this case, for example, MR data may be transmitted through wireless communication, and electric power may be transmitted through wired communication via the first transmission/reception unit coupling mechanism 300 and the second transmission/reception unit coupling mechanism 301. Alternatively, electric power may be transmitted through wireless communication, and MR data may be transmitted through wired communication via the first transmission/reception unit coupling mechanism 300 and the second transmission/reception unit coupling mechanism 301.

### Other Exemplary Embodiments

In the foregoing exemplary embodiments, the components of the apparatuses illustrated in the diagrams are functional concepts and do not necessarily need to be physically configured as illustrated in the diagrams. In other words, the specific forms of distribution or integration of the apparatuses are not limited to the illustrated ones, and all or part of the apparatuses can be functionally or physically distributed or integrated into any units depending on various loads and usages. All or part of the processing functions for the apparatuses to perform can be implemented by a CPU and programs to be analyzed and executed by the CPU, or as wired logic hardware.

All or part of the processes described to be automatically performed in the foregoing exemplary embodiments can be manually performed. All or part of the processes described to be manually performed can be automatically performed using known methods. Furthermore, the processing procedures, control procedures, specific names, and information including various types of data and parameters described above or illustrated in the drawings can be freely modified unless otherwise specified.

According to at least any one of the above-described exemplary embodiments, the number of cables installed between the table and the frame are reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A magnetic resonance imaging apparatus comprising:
a top plate on which a reception coil for receiving a magnetic resonance signal is disposed;
a top plate communication unit disposed in an interior of the top plate and configured to be movable inside the top plate; and
a frame communication unit disposed in a position at one end of a frame having a bore where the top plate is inserted,
wherein communication is executed between the top plate communication unit and the frame communication unit.

2. The magnetic resonance imaging apparatus according to claim 1, further comprising:
a top plate control unit configured to insert the top plate into the bore,
wherein the top plate communication unit is moved together with the top plate until the top plate communication unit is positioned in a communication position where communication between the top plate communication unit and the frame communication unit is possible, and after the top plate communication unit is positioned in the communication position, the top plate communication unit is stopped at the communication position regardless of an insertion position of the top plate.

3. The magnetic resonance imaging apparatus according to claim 2, further comprising a communication position control unit configured to control a position of the top plate communication unit inside the top plate to cause the top plate communication unit to move until the top plate communication unit is positioned in the communication position, and to cause, after the top plate communication unit is positioned in the communication position, the top plate communication unit to stop at the communication position regardless of an insertion position of the top plate.

4. The magnetic resonance imaging apparatus according to claim 2, further comprising:
a first coupling mechanism disposed on the top plate communication unit; and
a second coupling mechanism disposed on the frame communication unit,
wherein the first coupling mechanism and the second coupling mechanism causes the top plate communication unit to stop at the communication position regardless of an insertion position of the top plate by coupling with each other when the top plate communication unit is moved to the communication position.

5. The magnetic resonance imaging apparatus according to claim 1, wherein the communication between the top plate communication unit and the frame communication unit includes at least any one of transmission of magnetic resonance data which has been obtained through digitization of the magnetic resonance signal received by the reception coil, and transmission of electric power to be supplied to the reception coil.

6. The magnetic resonance imaging apparatus according to claim 1, wherein the communication between the top plate communication unit and the frame communication unit is executed wirelessly.

7. The magnetic resonance imaging apparatus according to claim 5, wherein the transmission of the magnetic resonance data is executed via an optical fiber.
